(19) United States
(12) Patent Application Publication
(10) Pub. No.: US 2009/0114507 A1
(43) Pub. Date: May 7, 2009

(54) Integrated overhead transport system with stationary drive

(75) Inventors: Barry Kitazumi, Milpitas, CA (US); Mihir Parikh, Los Altos Hills, CA (US); Martin P. Aalund, Sunnyvale, CA (US); Michael D. Brain, Monte Sereno, CA (US)

Correspondence Address: CARR & FERRELL LLP, 2200 GENG ROAD, PALO ALTO, CA, 94303, US

(73) Assignee: Aquest Systems Corporation

(21) Appl. No.: 11/983,353

(22) Filed: Nov. 7, 2007

(51) Int. Cl. B65G 47/04; B65G 65/02; B65H 1/00; B66C 13/22; H01L 21/677

(52) U.S. Cl. 198/370.09; 212/270; 212/331; 414/225.01; 414/281

(57) ABSTRACT

A transport system is provided to move an article from a conveyance section to a location. The conveyance section transports the article using a pair of transport belts. A lift lowers the article downward between the pair of transport belts. A hoist translates the article beneath the conveyance section to the location while supporting the article from above. The article may include a FOUP, semiconductor wafer, substrate for the manufacture of display devices or photovoltaics. The hoist may comprise a carriage and a gripper configured to grasp and vertically move the article while suspended beneath the carriage.

### CROSS-REFERENCE TO RELATED APPLICATIONS

This application is related to U.S. Pat. No. 7,281,623 entitled “Transport System Including Vertical Rollers” and filed on Apr. 18, 2006; U.S. patent application Ser. No. 11/897,013 entitled “Conveyor Transfer System” and filed on Aug. 27, 2007; U.S. patent application Ser. No. 11/764,161 entitled “Transport System Including Vertical Rollers” and filed on Jun. 15, 2007; U.S. patent application Ser. No. 11/764,755 entitled “Conveyor System Including Offset Section” and filed on Jun. 18, 2007; and U.S. patent application Ser. No. 11/818,657 entitled “Systems and Methods for Transport Through Curves” and filed on Jun. 14, 2007. The disclosures of each of the aforementioned applications are incorporated herein by reference.

### BACKGROUND OF THE INVENTION

1. Field of the Invention

The current invention relates to transport systems and methods for conveying articles along a conveyance path, and in some embodiments to conveying semiconductor wafers in a semiconductor fabrication facility.

2. Related Art

Transport systems are widely employed in industrial manufacturing facilities to convey articles between work stations. Originally, these systems were manual and workers moved articles by hand or by cart. Modern factories have developed specialized equipment to convey articles automatically. In particular, semiconductor fabrication facilities currently use automated transport systems to move semiconductor wafers during the manufacturing process. Typically, a batch of wafers may be conveyed together in a container known as a Front Opening Unified Pod (FOUP). Semiconductor wafer manufacturers have sought to increase manufacturing productivity by using transport systems that efficiently convey wafers from machine to machine without exposing the wafers to excessive contamination, to excessive vibration; or to excessive acceleration and deceleration forces.

Existing transport systems employ vehicle-based devices to grasp a FOUP using a top handle and move the FOUP from one location to another location. For example, a vehicle may be used to grasp a FOUP, raise the FOUP to a higher level, move the FOUP to a new position above a destination, lower the FOUP onto the destination, and then release the FOUP. After the vehicle has released the FOUP, the vehicle may then be dispatched to a location of a next FOUP requiring similar movement. While the vehicle is transporting the FOUP, the vehicle is considered loaded. After the vehicle has released the FOUP and before the vehicle grasps the next FOUP, the vehicle is considered empty. A period of time during which the vehicle is empty, for example the period of time during which the empty vehicle moves from the location where the vehicle released the first FOUP to the location where the vehicle grasps the next FOUP, increases the overall time required to deliver FOUPs to their destinations. Such delays may cause process equipment to become idle waiting for the arrival of material to process. The period of time the vehicle is empty may lead to a bottleneck and cause traffic congestion in a fabrication facility due to an inefficient use of resources. These transport and delivery vehicles require significant power for onboard controls and motors. This power is typically provided using complex and expensive power coupling systems such as inductive coupling.

### BRIEF DESCRIPTION OF THE DRAWINGS

FIG. 1 is a perspective view of a conveyance section, according to various embodiments of the invention.

FIGS. 2A-C illustrate a conveyance section comprising a lift at several progressive stages of operation, according to various embodiments of the invention.

FIGS. 3A-H illustrate a transfer system comprising a conveyance section, a life, a hoist, and machine tool load ports, at several progressive stages of operation, according to various embodiments of the invention.

FIG. 4A illustrates a hoist, according to various embodiments of the invention.

FIGS. 4B-C illustrate alternative pulley arrangements configured to couple the cable with the gripper pulley.

FIG. 5 illustrates a power and communications interface for a hoist, according to various embodiments of the invention.

FIG. 6 illustrates a method of transferring an article from a conveyance section to a machine load port, according to various embodiments of the invention.

### SUMMARY OF THE INVENTION

A system comprises a conveyance section including a first transport belt and a second transport belt. The first and second transport belts are disposed on either side of a conveyance path. The conveyance section is configured to convey an article along the conveyance path. The first and second transport belts are configured to be separated by a distance suitable for placement of the article therebetween. The system also comprises a lift configured to lower the article along a vertical axis between the first and the second transport belts. The system further comprises a hoist including a carriage, a connective element, and a motor. The carriage has a gripper configured to engage the article. The connective element is attached to the carriage. The motor is external to the carriage and configured to move the carriage laterally by translating the connective element. The connective element may be a cable. The hoist and the conveyance section may be integrated. The article may comprise a FOUP.

A method of moving an article from a conveyance section to a location is disclosed. The article is transported using a first transport belt and a second transport belt of the conveyance section. The article is lowered by passing the article downward between the first transport belt and the second transport belt. The article is translated beneath the conveyance section to the location while the article is supported from above. Lowering the article may include lifting the article from the conveyance section such that the article no longer touches the transport belts and rotating the article such that the article may pass downward between the first and second transport belts. The article may comprise a FOUP and the location may comprise an equipment load port.

A system for transporting an article comprises a support structure, a carriage, a first connective element, a first motor, and a gripper. The carriage is disposed below the support structure and configured to move laterally while being supported by the support structure. The first connective element is coupled with the carriage and approximately horizontally oriented. The first motor is coupled with the first connective element. The first motor is configured to laterally translate the carriage using the first connective element. The gripper is suspended beneath the carriage. The gripper is configured to engage the article and support the article from above. The article may comprise a FOUP. The first motor may be disposed external to the carriage. The carriage may include a lift mechanism having an approximately vertically oriented connective element. The gripper may be suspended below the carriage using the vertically oriented connective element, and the lift mechanism may be configured to lift the gripper using the vertically oriented connective element. A second connective element may be coupled with the lift mechanism and a second motor may be coupled with the second connective element. The second motor may be configured translate the second connective element to cause the lift mechanism to raise or lower the gripper. A clutch may be disposed between the lift mechanism and the second motor. The second motor may be disposed external to the carriage.

A system for moving an article comprises a carriage configured to move the article and an electrically conductive connective element coupled with the carriage. The connective element is configured to laterally translate the carriage and electrically couple the carriage with an electrical source. The system may further comprise a gripper suspended below the carriage. The gripper may be configured to engage a FOUP. The electrical source may comprise an electrical power source, and the electrically conductive connective element may be configured to provide electrical power to the carriage. The electrical source may comprise a first electronic data transceiver and the carriage may comprise a second electronic data transceiver. The electrically conductive connective element may be configured to communicatively couple the first and second electronic data transceivers to convey an electronic communication therebetween.

### DETAILED DESCRIPTION

During semiconductor fabrication, it is generally desirable to transport semiconductor wafers at very high speeds between process and metrology equipment throughout a fabrication facility. The wafers are typically transported inside a carrier called a FOUP. The FOUP can be transported on a transport system such as those disclosed in U.S. Pat. No. 7,281,623 and U.S. patent application Ser. Nos. 11/764,161, 11/764,755, and 11/818,657. Embodiments are described herein with reference to the conveyance and transfer of FOUPs by way of example; however, these and other embodiments are generally applicable to other articles that may be conveyed and transferred, and the embodiments described herein are in no way intended to be limited to the conveyance and transfer of FOUPs.

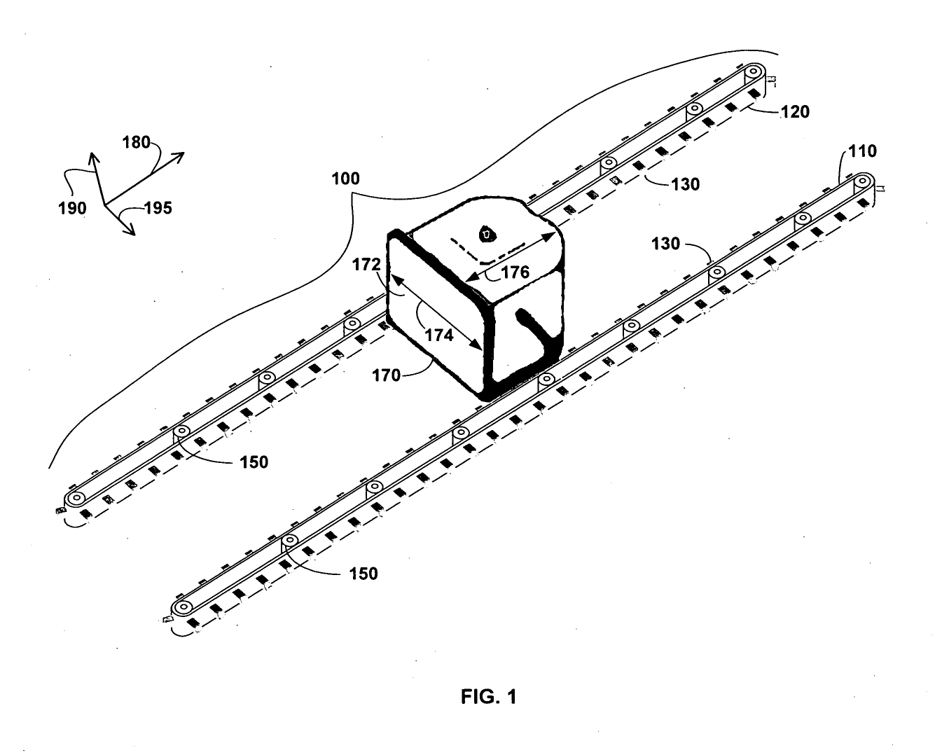

FIG. 1 is a perspective view of a conveyance section 100 according to various embodiments of the invention. The conveyance section 100 comprises a first transport belt 110, a second transport belt 120, a plurality of rollers 150, and optional support protrusions 130. The plurality of rollers 150 are configured to guide and optionally support the transport belts 110 and 120. The support protrusions 130 extend from the transport belts 110 and 120 to support an article such as a FOUP 170. In various embodiments, a cross section of the transport belts 110 and/or 120 may be vertically oriented along a vertical axis 190, horizontally oriented along a horizontal axis 195, or slanted between horizontal and vertical. In some embodiments, at least some portion of the transport belts 110 and/or 120 may be substituted with alternative support members such as rollers. In these embodiments, support protrusions 130 may also optionally be coupled with the alternative support members and configured to support the article.

The conveyance section 100 is configured to convey the FOUP 170 in a conveyance direction 180 along a conveyance path between the transport belts 110 and 120. The conveyance section 100 may be configured with multiple instances of conveyance sections 100. The FOUP 170 is characterized by a width 174 (shown parallel to a FOUP door 172) that is longer than a length 176 (shown perpendicular to the FOUP door 172). During conveyance, the width 174 is perpendicular to the transport belts 110 and/or 120. For example, the width 174 may be approximately 390 mm, and the length 176 may be approximately 356 mm. The spacing between transport belts 110 and 120 is typically configured to support the FOUP 170 when the FOUP 170 is oriented such that the width 174 and FOUP door 172 are approximately perpendicular to the transport belts 110 and 120 along a horizontal axis 195.

Specific mechanical, electrical, and software interfaces are defined to enable a variety of devices to directly access the FOUP 170 disposed on the transport belts 110 and 120. Embodiments of such interfaces include a mechanical interface such as the kinematic interface defined by the trade organization SEMI in the document number E57-0600 entitled “Mechanical Specification for Kinematic Couplings used to Align and Support 300 mm Wafer Carriers” and the electrical interface and software communications interface defined by the SEMI standard E84-0305 entitled “Specification for Enhanced Carrier Handoff Parallel I/O Interface.” The kinematic interface features three kinematic coupling pins on a kinematic mount, the kinematic coupling pins being configured to mate with three corresponding depressions disposed on the bottom of the FOUP 170 when the FOUP 170 is placed in proper alignment with the kinematic mount.

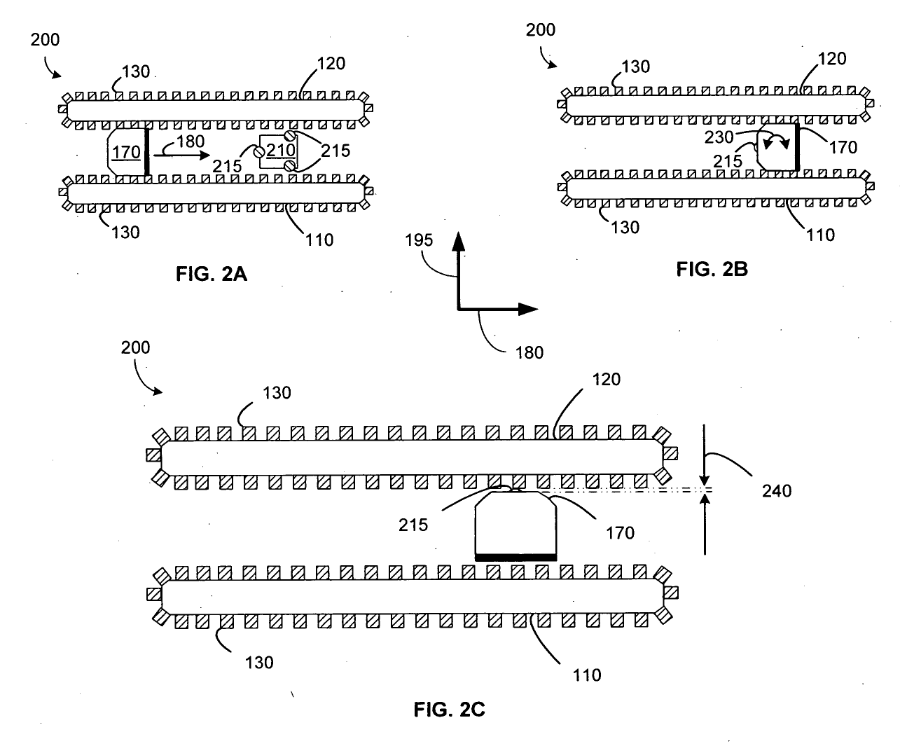

FIGS. 2A-C illustrate a conveyance section 200 comprising a lift 210 at several progressive stages of operation, according to various embodiments of the invention. The conveyance section 200 is an embodiment of the conveyance section 100 described with reference to FIG. 1, and the conveyance section 200 may comprise any embodiment of the conveyance section 100 further comprising the lift 210. The conveyance section 200 comprises a first transport belt 110, a second transport belt 120, a plurality of optional support protrusions 130, and the lift 210. The lift 210 may be integrated with the conveyance section 200, or the lift 210 may be independent of the conveyance section 200 while also configured to function in conjunction with the conveyance section 200.

The lift 210 is configured to include a kinematic interface. The lift 210 may alternately be configured to engage a FOUP 170 using other means such as interfacing with an optional automatic guided vehicle (AGV) interface, FOUP pin holes, or a FOUP top handle. The lift 210 may be disposed between the transport belts 110 and 120 such that the lift 210 can be raised and lowered along a vertical axis 190 (FIG. 1) under the FOUP 170 when the FOUP 170 is disposed in a location above the lift 210. The lift 210 may be configured to raise the FOUP 170 above a horizontal plane of the transport belts 110 and 120. The horizontal plane may be defined by horizontal axes 180 and 195 at a position along vertical axis 190 (FIG. 1) wherein the horizontal plane intersects a portion of transport belts 110 and/or 120 or supporting structures such as wheels and drive mechanisms. The lift 210 may also be configured to lower the FOUP 170 below the horizontal plane of the transport belts 110 and 120. The lift 210 may also be configured to rotate the FOUP 170 in a direction of rotation 230, as illustrated in FIG. 2B. The direction of rotation 230 may be in a horizontal plane defined by the horizontal axes 180 and 195.

The lift 210 may also be configured to rotate the FOUP 170 in a vertical plane defined by the horizontal axis 195 and the vertical axis 190. By rotating the FOUP 170 in the vertical plane, the FOUP 170 may tilt such that an edge of the FOUP 170 closest to the transport belt 110 may be at a different elevation, such as higher, than an edge of the FOUP 170 closest to the transport belt 120. The tilted FOUP 170 may have a narrower width projected downward along the vertical axis 190 than the untilted FOUP 170, and therefore, the lift 210 may be able to lower the tilted FOUP 170 downward between the transport belts 110 and 120. The lift 210 may be configured to rotate the FOUP 170 in the horizontal plane and the vertical plane simultaneously, or in a step-wise fashion resulting in rotation in both planes prior to lowering the FOUP 170 downward between the transport belts 110 and 120. The lift 210 may be configured to rotate the FOUP 170 in the vertical plane and/or the horizontal plane simultaneously with raising or lowering the FOUP 170 along the vertical axis 190. While the present discussion is specifically directed to the FOUP 170, for other articles an appropriate rotation to align the article to pass between the first and second transport belts 110 and 120 may be about a rotation axis that is not within either the horizontal or vertical planes.

The conveyance section 200 is configured to move the FOUP 170 proximate to the lift 210 and optionally stop the FOUP 170 in a location approximately over the lift 210. Interface features, such as kinematic coupling pins 215 disposed on a top surface of the lift 210, may optionally interact and couple with corresponding interface features on a bottom surface of the FOUP 170, such as three kinematic holes. The kinematic coupling pins 215 and related features are configured to maintain proper alignment between the FOUP 170 and the lift 210. After the FOUP 170 is aligned and coupled with the lift 210, the lift 210 may be used to lift the FOUP 170 above the transport belts 110 and 120 or at least off of the support protrusions 130. Once the FOUP 170 is above and no longer in substantial contact with the transport belts 110 and 120 and/or the support protrusions 130, the lift 210 may rotate the FOUP 170 freely in the rotational direction 230. The lift 210 may rotate the FOUP 170 by approximately a positive or negative 90 degrees. The lift 210 may rotate the FOUP 170 by any arbitrary amount before, during, or after raising the FOUP 170 along the vertical axis 190 as appropriate or necessary to align the FOUP 170 with another conveyance section 200 or other destination.

For example, FIG. 2C illustrates the conveyance section 200 after the lift 210 has rotated the FOUP 170 by approximately 90 degrees. After the lift 210 rotates the FOUP 170 by approximately 90 degrees, the smaller FOUP length 176 will be perpendicular to the transport belts 110 and 120 along the horizontal axis 195. When the FOUP 170 is oriented in this manner, the conveyance section 200 is configured to provide a clearance 240 between the FOUP 170 and the support protrusions 130 of the transport belts 110 and 120. The clearance 240 enables the lift 210 to lower the FOUP 170 downward between the transport belts 110 and 120 without contacting the transport belts 110 and 120 or the support protrusions 130. The lift 210 may be configured to lower the FOUP 170 below the horizontal plane of the transport belts 110 and 120 by any amount as needed to deliver the FOUP 170 to its next destination. The lift 210 may be configured to lower the FOUP 170 below the horizontal plane of the transport belts 110 and 120 by at least the height of one FOUP 170, two FOUPs 170, three FOUPs 170, four FOUPs 170, or more. Once the FOUP 170 has been lowered below the horizontal plane of the transport belts 110 and 120, the FOUP 170 may be rotated by any arbitrary amount as appropriate or necessary to align the FOUP 170 with another conveyance section 200 or other destination, or held in place.

Because the lift 210 may only be required to lift the FOUP 170 above the transport belts 110 and 120 far enough to enable the FOUP 170 to rotate freely before lowering the FOUP 170 downward between the transport belts 110 and 120, little clearance above the conveyance section 200 is required. Therefore, the conveyance section 200 and/or the lift 210 may be supported by a structure overhead, for example by a ceiling of a room. Overhead support of the conveyance section 200 enables an open and unobstructed work space below the conveyance section 200.

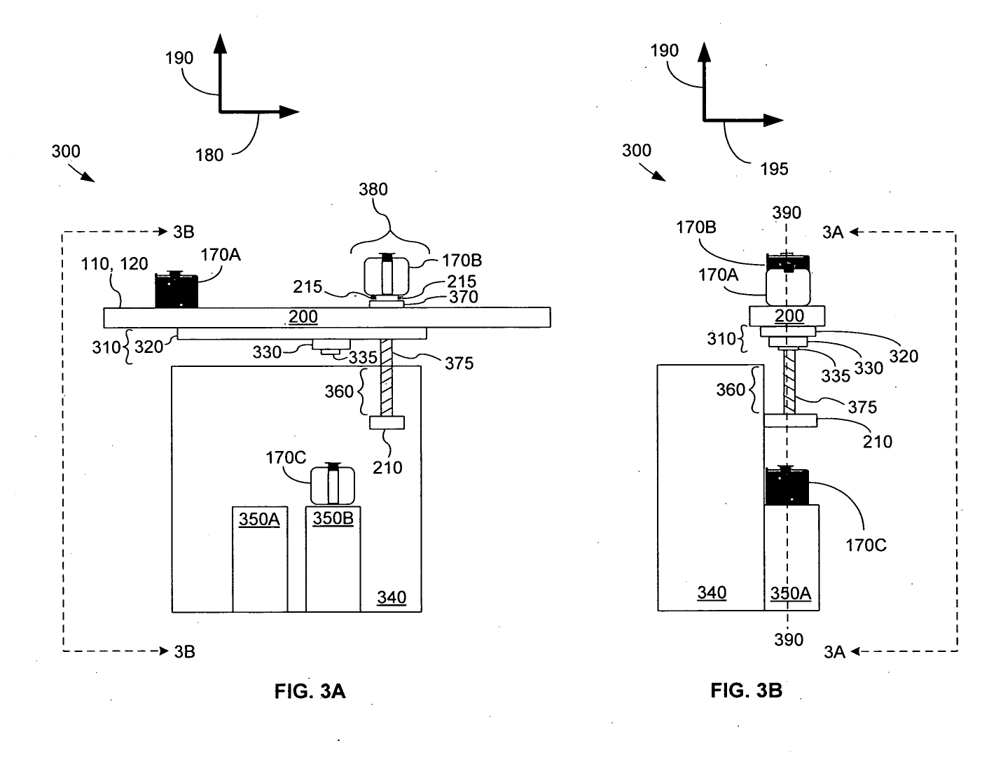

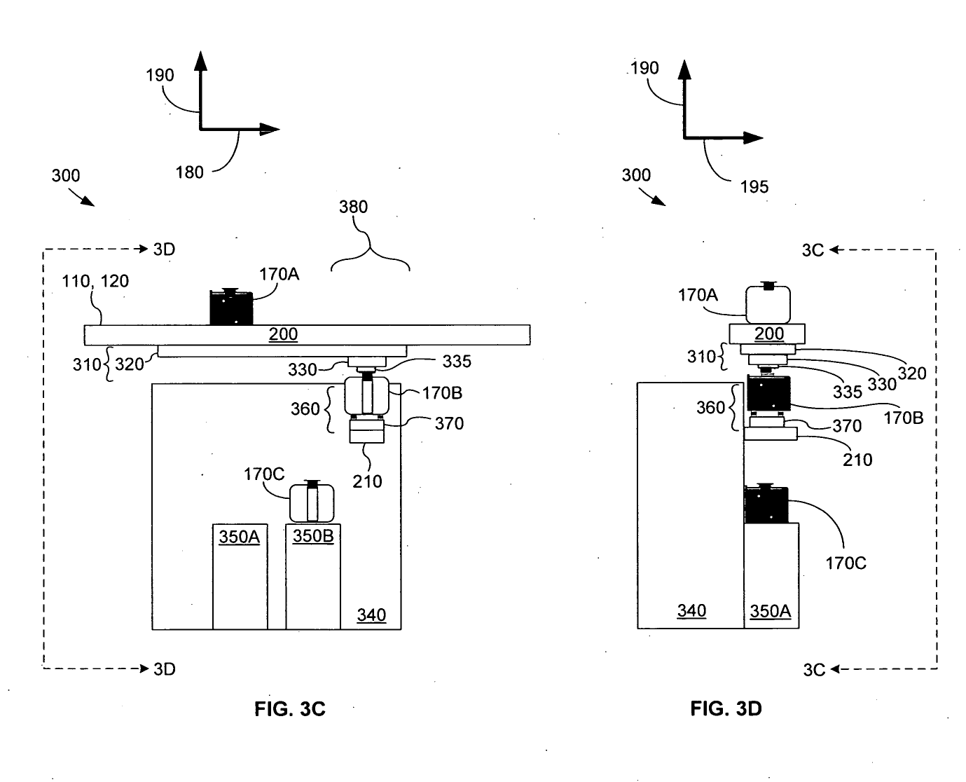

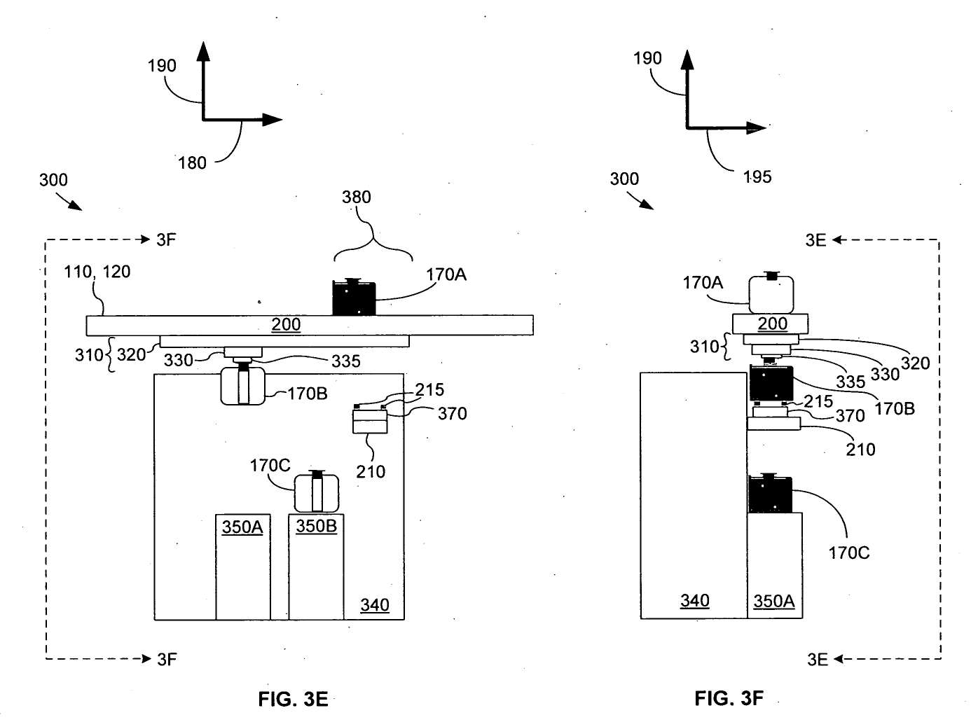

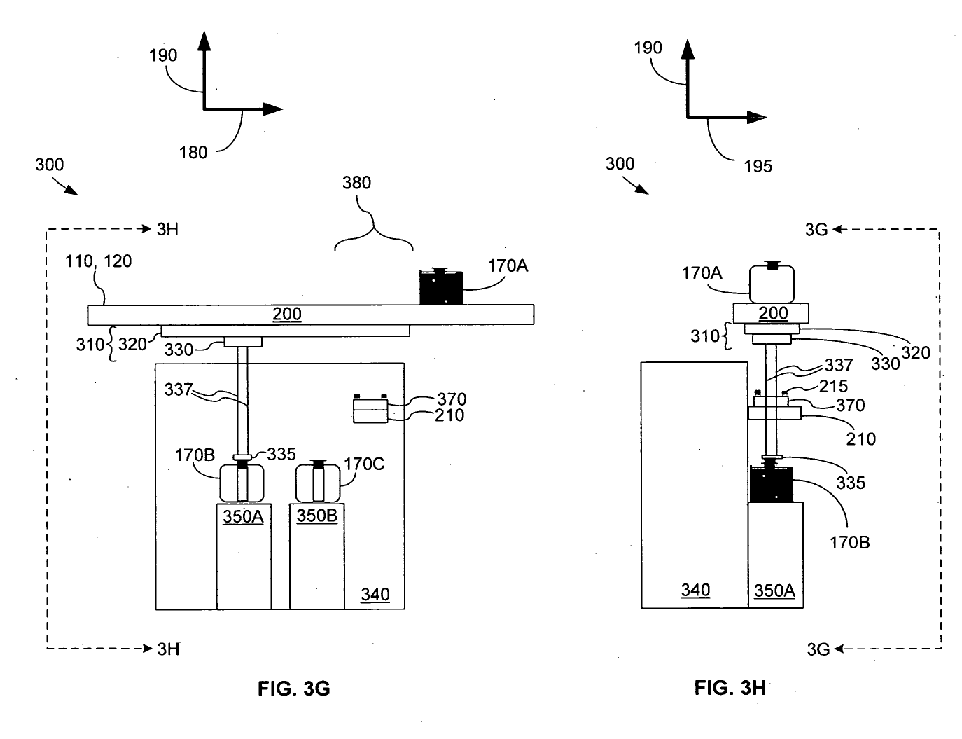

FIGS. 3A-H illustrate a transfer system comprising a conveyance section 200, a lift 210, a hoist 310, and machine load ports 350A and 350B, at several progressive stages of operation, according to various embodiments of the invention. FIGS. 3B, 3D, 3F, and 3H are alternate views of FIGS. 3A, 3C, 3E, and 3G taken along lines 3B, 3D, 3F, and 3H, respectively, and vice-versa. As illustrated, the transfer system 300 is configured to transfer a FOUP such as FOUP 170B from the conveyance section 200 to a destination process or metrology equipment 340. As illustrated in FIG. 3B, the conveyance section 200 comprising transport belts 110 and 120 may be disposed partially or completely above the process or metrology equipment 340 and be partially or completely vertically aligned with the machine load ports 350A and 350B, the lift 210, and/or the hoist 310 in a vertical plane 390 (seen edge-on in FIG. 3B). Vertical alignment of the conveyance section 200, lift 210, hoist 310, and/or machine load ports 350A and 350B provide an efficient use of space and reduce a distance an article must travel during transfer. The lift 210 is disposed at an equipment transfer location 380 near the location of the process or metrology equipment 340 as illustrated in FIG. 3A. The lift 210 is configured to raise a lift support 370 between the transport belts 110 and 120 within the equipment transfer location 380. The lift support 370 is raised using a vertical lift member 375. The lift support 370 is configured to couple with the FOUP 170B for example using a three point kinematic interface comprising interface features such as kinematic coupling pins 215.

Using the lift support 370, the lift 210 is configured to raise the FOUP 170B from the transport belts 110 and 120 and rotate the FOUP 170B to provide a clearance 240 (FIG. 2) between the FOUP 170B and the transport belts 110 and 120. As illustrated in FIGS. 3C and 3D, the lift 210 is configured to lower the FOUP 170B between the first transport belt 110 and the second transport belt 120 to an intermediate location 360 below the conveyance section 200. The lift 210 may optionally rotate the FOUP 170B after the FOUP 170B is lowered below the horizontal plane of the transport belts 110 and 120.

The transport belts 110 and 120 may remain in motion while the lift 210 lowers the FOUP 170B, and therefore another article such as FOUP 170A may move toward the equipment transfer location 380 while the lift 210 is lowering the FOUP 170B. The transport belts 110 and 120 may convey another article such as FOUP 170A to the equipment transfer location 380 after the lift 210 lowers the FOUP 170B below the horizontal plane of the transport belts 110 and 120 such that the FOUP 170B does not obstruct a path of the FOUP 170A along the conveyance section 200. In some embodiments, the lift 210 may be configured to lower the FOUP 170B between the transport belts 110 and 120 in approximately two seconds so that a time delay between FOUPs 170 on conveyance section 200 can be as little as approximately two seconds. In some embodiments, the transport belts 110 and 120 may be slowed when the FOUP 170B is loaded or unloaded to avoid interference between the FOUP 170B being loaded or unloaded from transport belts 110 and 120 and another FOUP 170A being transported on the same transport belts 110 and 120.

The destination processing or metrology equipment 340 or a purge port may be configured in some embodiments to access the FOUP 170B while the FOUP 170B is located at the intermediate location 360. The purge port may be configured to charge the FOUP 170 with nitrogen, clean, dry air, or an inert gas. At the intermediate location 360, the equipment 340 may open the FOUP front door 172 and process or perform measurements of the contents, such as semiconductor wafers disposed within the FOUP 170B. Alternatively, when the processing or metrology equipment 340 is ready to receive the FOUP 170B, the transfer system 300 may transfer the FOUP 170B from the intermediate location 360 onto an equipment load port 350A using an apparatus such as the hoist 310.

The hoist 310 comprises a hoist rail 320, a carriage 330, and a gripper 335. The hoist 310 is configured to laterally move the carriage 330 along the hoist rail 320. The hoist rail 320 may comprise for instance one or more tracks configured to couple with and support the carriage 330. The one or more tracks may be approximately horizontally oriented. The carriage 330 may comprise moveable support elements such as runners, blades, and/or guide wheels configured to couple with the one or more tracks of the hoist rail 320, support the carriage 330, and enable the carriage 330 to move laterally along the hoist rail 320. The hoist may be configured to be driven and operated by one or more motors external to the carriage 330 and/or the gripper 335, thereby reducing a weight of the carriage 330 and/or the gripper 335 and enabling quick and smooth operation having low vibration.

The carriage 330 is configured to suspend the gripper 335 below the carriage 330. The carriage 330 may also comprise a lift mechanism configured to raise and lower the gripper 335. The gripper 335 may be configured to engage an article such as a FOUP 170 using active or passive means. For example, the gripper 335 may actively grasp a top handle of the FOUP 170, or the gripper 335 may passively couple with the top handle of the FOUP 170 using an engagement structure with a C-shaped opening.

When the FOUP 170B is located at the intermediate location 360, the hoist 310 may be configured to move the carriage 330 along the hoist rail 320 to the equipment transfer location 380 above the FOUP 170B, lower the gripper 335 proximate to the FOUP 170B, and engage the kinematic top handle disposed on the top surface of the FOUP 170B using the gripper 335, as illustrated in FIGS. 3C and 3D.

As illustrated in FIGS. 3E and 3F, the hoist 310 is configured to lift the FOUP 170B from the lift support 370 at the intermediate location 360 and laterally move the carriage 330 until the gripper 335 is above the destination equipment load port 350A. As illustrated in FIGS. 3G and 3H, the hoist 310 is configured to lower the gripper 335 using vertical supports 337 along the vertical axis 190 until the FOUP 170B rests on, or couples with, the equipment load port 350A. The hoist 310 may then release the FOUP 170B and optionally lift the gripper 335 proximate to the carriage 330. The hoist 310 may be configured to translate the gripper 335 along the vertical axis 190 and translate the carriage 330 along the horizontal axis 180 simultaneously, or in a step-wise fashion in which the carriage 330 and the gripper 335 translate along only one of the vertical axis 190 and horizontal axis 180 at a time. For example, the hoist 310 may be configured to hold the carriage 330 stationary along the hoist rail 320 while translating the gripper 335 along the vertical axis 190, and also to laterally translate the carriage 330 along the hoist rail 320 while holding the gripper 335 at a constant vertical position along the vertical axis 190.

The hoist 310 may be integrated with the conveyance section 200 and/or the lift 210. Integration of the hoist 310 and the conveyance section 200 and/or the lift 210 may reduce misalignment between the gripper 335, the FOUP 170B located at the intermediate location 360, and the load ports 350A and 350B. In addition, the hoist 310 may be configured to share a common power and/or communications infrastructure as well as mechanical and seismic supports with the conveyance section 200 and/or lift 210.

The lift 210 may be integrated with a load port 350 of the processing or metrology equipment 340 such as load port 350A and/or 350B. The lift 210 may be integrated with the conveyance section 200 and/or the hoist 310. The lift 210 may also be integrated with an apparatus configured to open the FOUP front door 172. Integration between the equipment load port 350 and the lift 210 may reduce or eliminate intermediate steps and mechanisms. For example, a lift 210 integrated with a load port 350 may transfer a FOUP 170 directly from the transport belts 110 and 120 to a machine load port 350. After the FOUP 170 is transferred to the machine load port 350 where the FOUP front door 172 may be opened to enable access to semiconductor wafers located within the FOUP 170.

The lift 210 may be configured to have an additional axis of motion (not shown) such that the lift 210 may be moved laterally in synchronization with the movement of the FOUP 170 along the transport belts 110 and 120. The lift 210 having the additional axis of motion may be configured to enable a smooth transfer of the FOUP 170 onto and off of the transport belts 110 and 120 while the transport belts 110 and 120 maintain a constant velocity. When a position along the vertical axis 190 and a velocity along the conveyance direction 180 of the lift 210 having the additional axis of motion matches the position and velocity of the FOUP 170, the lift 210 may raise the lift support 370 to couple with the FOUP 170, lift the FOUP 170, rotate the FOUP 170, and lower the FOUP 170 to below the horizontal plane of the transport belts 110 and 120. The lift 210 may then move the FOUP 170 in both horizontal and vertical directions to position the FOUP 170 at the destination load port 350.

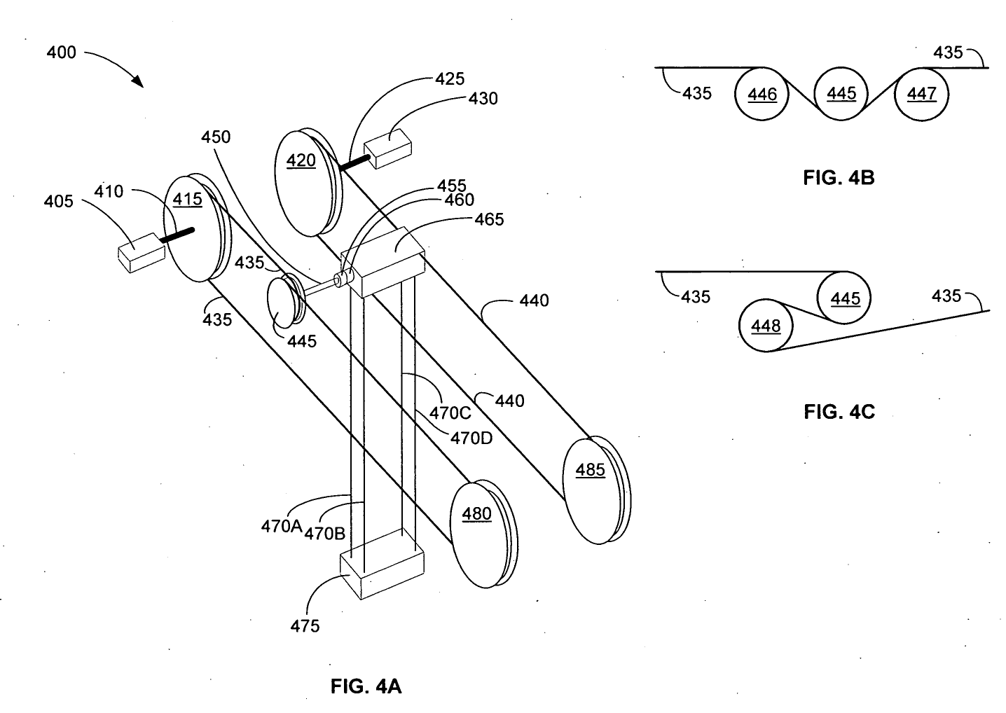

FIG. 4A illustrates a hoist 400, according to various embodiments of the invention. The hoist 400 is an embodiment of hoist 310, described with reference to FIG. 3. The hoist 400 comprises a carriage 465 configured to move laterally while the carriage 465 is supported by a hoist rail (not shown) such as hoist rail 320 (FIG. 3). A brake (not shown) may optionally be configured to hold the carriage 465 stationary along the hoist rail 320 when the brake is engaged, or allow the carriage 465 to move laterally along the hoist rail 320 when the brake is disengaged. A cable 440 is configured in a loop between a drive pulley 420 and a return pulley 485, the cable 440 configured to couple the carriage 465 with the drive pulley 420. The drive pulley 420 is coupled with a drive motor 430 via a drive shaft 425. The drive motor 430 is configured to rotate the drive pulley 420 via the drive shaft 425, and thereby cause the cable 440 to move the carriage 465 laterally toward or away from the drive pulley 420.

A gripper 475 is suspended beneath the carriage 465 using one or more vertical supports 470, such as vertical supports 470A, 470B, 470C, and 470D. The gripper 475 is an embodiment of gripper 335 described with reference to FIG. 3. The gripper 475 is configured to engage a FOUP 170, for example, by grasping a kinematic top handle disposed on the FOUP 170 or by other techniques as known in the art. The gripper 475 may include sensors and/or be configured to receiver power, control signals, and/or data communications from the carriage 465 via electrical connections along one or more vertical supports 470. The vertical supports 470 may comprise connective elements configured to physically support the gripper 475 and enable the carriage 465 to raise and lower the gripper 475 such as tape, belts, bands, cable, chains, wire, rods, screws, etc.

The carriage 465 may comprise a lift mechanism (not shown) configured to use the vertical supports 470 to raise and/or lower the gripper 475. The lift mechanism may comprise for example a pulley and/or a spool configured to reel the vertical supports 470 in and out, where the vertical supports 470 comprise tape, belts, bands, cable, chains, wire, or the like. The lift mechanism may comprise a screw drive where the vertical supports 470 comprise screws. The lift mechanism may comprise gears and/or wheels where the vertical supports 470 comprise rods. Other combinations of lift mechanisms and vertical supports 470 may be utilized as are known in the art.

A motor (not shown) for raising and/or lowering the gripper 475 may be integrated with the lift mechanism on the carriage 465, or the lift mechanism may be driven using an external motor such as motor 405 via a lift mechanism drive shaft 450. A clutch 455 may be coupled with the drive shaft 450. The clutch 455 is configured to decouple rotational movement of the drive shaft 450 from the lift mechanism when the clutch 455 is in a disengaged state. Likewise, the clutch 455 is configured to cause the lift mechanism to raise or lower the vertical supports 470 in response to rotational movement of the drive shaft 450 when the clutch 455 is in an engaged state. When the clutch 455 is in the disengaged state, the drive shaft 450 may rotate freely without affecting the lift mechanism. A brake 460 may be coupled with the lift mechanism and/or drive shaft 450. The brake 460 may be configured to hold the drive shaft 450 stationary such that the brake 460 does not allow any rotational movement of the drive shaft 450. The brake 460 may be configured to hold the lift mechanism stationary such that the brake 460 does not allow the vertical supports 470 to raise or lower the gripper 475. The clutch 455 and the brake 460 may be disposed in alternate configurations other than those shown, such as integrated within the carriage 465, integrated within a gripper pulley 445, or integrated with the drive shaft 450.The gripper pulley 445 is coupled to the drive shaft 450 such that when the gripper pulley 445 rotates, the drive shaft 450 also rotates. A cable 435 is configured in a loop between a drive pulley 415 and a return pulley 480. The cable 435 is also coupled with the gripper pulley 445.

FIGS. 4B-C illustrate alternative pulley arrangements configured to couple the cable 435 with the gripper pulley 445. As illustrated in FIG. 4A, the cable 435 may loop around the gripper pulley 445. As illustrated in FIGS. 4B and 4C, additional pulleys such as gripper guide pulleys 446, 447, and/or 448 may be disposed in conjunction with the gripper pulley 445 to guide the cable 435 around a cylindrical surface of the gripper pulley 445. In the embodiments illustrated in FIGS. 4B and 4C, the cable 435 does not form a full loop around the gripper pulley 445 so that the cable 435 does not rub against itself. A motor 405 is coupled with the drive pulley 415 via a drive shaft 410 and configured to cause the drive pulley 415 to rotate. In some embodiments, a clutch (not shown) may be coupled with the motor 405, drive shaft 410, and/or drive pulley 415, where the clutch is configured to selectively engage and disengage the drive pulley 415 and the motor 405. When the clutch is in an engaged state, the motor 405 is configured to cause the pulley 415 to rotate via the drive shaft 410. When the clutch is in a disengaged state, the motor 405 and the drive pulley 415 are decoupled from one another in that rotation of one does not affect the rotation of the other. In some embodiments, the motor 405 may be configured to optionally turn freely in response to rotation of the pulley 415 without the use of a separate clutch mechanism coupled with the motor 405, drive shaft 410, or drive pulley 415.

The hoist 400 may be configured to move the carriage 465 laterally while the lift mechanism maintains a constant vertical position of the gripper 475, move the gripper 475 vertically while the carriage 465 maintains a constant horizontal position, or move the carriage 465 laterally while the lift mechanism moves the gripper 475 vertically. For example, the motor 430 may drive the cable 440 via the drive shaft 425 and the drive pulley 420, and thereby cause the carriage 465 to move laterally. To prevent the gripper 475 from raising or lowering, the clutch 455 may be configured to disengage the drive shaft 450 from the lift mechanism, and the brake 455 may be engaged to cause the lift mechanism to hold a position of the vertical supports 470 constant regardless of any movement of the drive shaft 450. In this example, the cable 435 may be held in a constant position and the gripper pulley assembly 445 allowed to rotate as needed as the carriage 465 moves laterally.

Alternatively, the cable 435 may move in synchrony with the cable 440. In this configuration, the brake 460 may be engaged to hold the drive shaft 450 and consequently the gripper pulley assembly 445 such that they do not rotate. Therefore, lateral movement of the cable 435 acts to cause the carriage 465 to move laterally. Further, in this configuration, the hoist 400 may rely on the motor 405 driving cable 435 to both move the carriage 465 laterally and move the gripper 475 vertically, depending on whether each of the clutch 455 and the brake 460 are engaged or disengaged. Therefore, the hoist 400 may be configured without the motor 430, drive shaft 425, drive pulley 420, return pulley 485, and cable 440.

In alternative embodiments, the cables 435 and 440 may be substituted with other connective elements such as belts, bands, chains, wire, rods, screws, or other drive mechanisms as known in the art, the drive mechanisms configured to use a motor external to the carriage 465 to cause the carriage 465 to move laterally and cause the lift mechanism to raise and lower the gripper 475. In these alternative embodiments, the pulleys 415, 420, 480, 485, and 445 along with the drive shafts 410, 425, and 450 may be substituted with other elements as appropriate to function with the substituted drive mechanisms. In some embodiments, a single motor may be employed to perform the functions of both motors 405 and 430. In some embodiments, one or both of motors 405 and 430 may be disposed on the carriage 465 rather than external to the carriage 465.

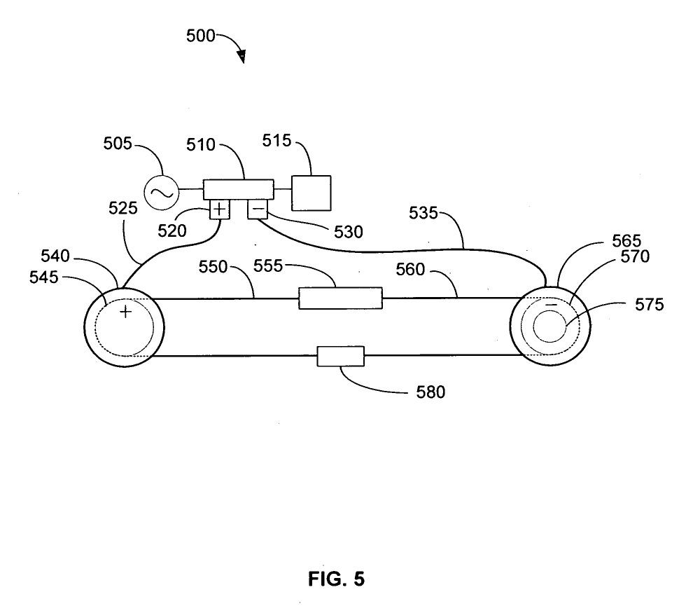

FIG. 5 illustrates a power and communications interface for a hoist 500, according to various embodiments of the invention. Hoist 500 is an embodiment of hoists 310 and 400. Hoist 500 is configured to use a same cable, or other connective element such as a band or belt, to laterally move a carriage 555 while also providing electrical power and/or electronic data communications to the carriage 555.

The carriage 555 is disposed between a positive pulley 540 and a negative pulley 565. The carriage 555 is an embodiment of carriages 330 and 465. The positive pulley 540 and negative pulley 565 are embodiments of pulleys 415, 420, 480, and 485. The positive pulley 540 and/or negative pulley 565 may be driven to cause the carriage 555 to move laterally using a motor and/or drive mechanism 575. The carriage 555 is coupled with the positive pulley 540 and negative pulley 565 using a cable loop, the cable loop comprising a positive segment 550 and a negative segment 560. The positive segment 550 and the negative segment 560 are each coupled with the carriage 555 at one end and coupled with an insulator 580 at the opposite end. The positive segment 550 and the negative segment 560 comprise electrically conductive cables and are configured to conduct electrical current and/or electrical data transmissions. The positive segment 550 is electrically coupled to a positive terminal at the carriage 555, and the negative segment 560 is electrically coupled to a negative terminal at the carriage 555.

In some embodiments, the positive pulley 540 may comprise a slip ring or mercury capsule configured to electrically couple the positive electrical conductor 525 with the positive segment 550, and/or the negative pulley 565 may comprise a slip ring or mercury capsule configured to electrically couple the negative electrical conductor 535 with the negative segment 560. The positive segment 550 is electrically coupled to a positive electrical conductor 525 via a conductive pulley surface 545. Likewise, the negative segment 560 is electrically coupled to a negative electrical conductor 535 via a conductive pulley surface 570.

The positive electrical conductor 525 is electrically coupled with a positive terminal 520 on a junction box 510, while the negative electrical conductor 535 is electrically coupled with a negative terminal 530 on the junction box 510. The junction box 510 is configured to couple the positive terminal 520 and the negative terminal 530 to an electrical source such as a power source 505, an electronic data communications transceiver 515, or both. The power source 505 may be an AC power source or a DC power source, and configured to provide power to the carriage 555 and/or one or more motors coupled with the pulleys 540 and 565. In embodiments where the power source 505 is an AC power source, a hot line transmitting the AC power may be electrically coupled with the positive terminal 520, and a neutral return line may be electrically coupled with the negative terminal 530. For example, the power source 505 may be a 220 volt AC power source. The electronic data communications transceiver 515 may be an Ethernet transceiver, a modem, a power line communications transceiver, or other data communications device configured to communicate with a matched data communications transceiver (not shown) disposed on the carriage 555.

The carriage 555 may comprise electronics configured to demodulate data communications transmitted simultaneously with electrical power over the positive segment 550 and/or negative segment 560. Alternatively, the carriage 555 may be configured to electrically couple communications received from the electronic data communications transceiver 515 to an article coupled with the carriage 555 such as a gripper or FOUP (not shown). The electronic data communications transceiver 515 may be communicatively coupled with one or more other electronic data communications transceivers, such as transceivers associated with a central control computer system, electronic data server, or computing device. Alternatively, the carriage 555 may be configured to electrically couple with the power source 505 via the positive segment 550 and/or the negative segment 560, while the carriage 555 uses line of sight (wireless) optical or wireless RF electronic communications (not shown) to couple with the electronic data communications transceiver 515.

In some embodiments, the junction box 510 may comprise a circuit breaker such as a residual current circuit breaker (RCCB) or ground fault circuit interrupter (GFCI) configured to monitor an electrical current passing through the positive terminal 520 and the negative terminal 530, and disconnect power from the positive terminal 520 and the negative terminal 530 when the electrical current is not balanced between the positive terminal 520 and the negative terminal 530.

Variations on the hoist 500 may be practiced using the teachings disclosed herein by one of ordinary skill in the art. For example, the carriage 555 may be substituted with another apparatus, such as a lift configured to change an, elevation of an article. The positive segment 550 and the negative segment 560 may each be substituted with another connective element such as a tape, band, belt, band, chain, wire, rod, or screw, such that the substituted connective element is configured to be electrically conductive. The pulleys 540 and 565 may be substituted for other conductive translational elements as appropriate and suitable to function with the chosen connective elements as known in the art. For example, screw drives may be used in place of pulleys when screws are chosen for the connective elements. The positive segment 550 and the negative segment 560 need not be coupled together using the insulator 580 to form a continuous loop, but may instead be wound onto spools disposed in place of the positive pulley 540 and the negative pulley 565. The hoist 500 may be configured to move the carriage 555 along a vertical axis, a horizontal axis, or any combination thereof. Multiple pulleys may be disposed to supplement pulleys 540 and 565.

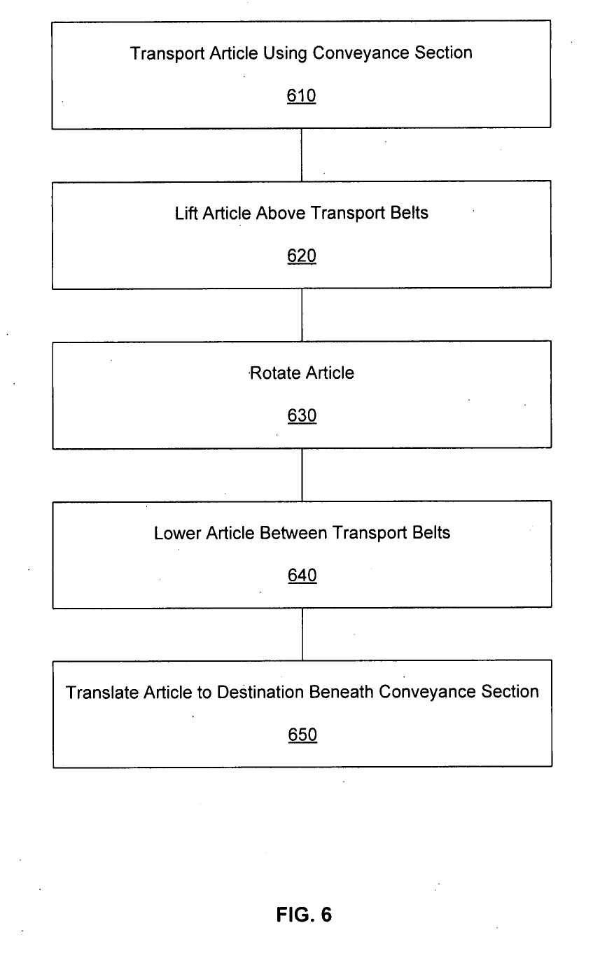

FIG. 6 illustrates a method of transferring an article from a conveyance section to a machine load port, according to various embodiments of the invention. The method described with reference to FIG. 6 may be performed in reverse in order to transfer the article from the machine load port to the conveyance section, according to various embodiments of the invention. The article may comprise a FOUP, a semiconductor wafer, a substrate used for manufacturing a liquid crystal, organic light emitting diode or other type of display device, a memory substrate (such as a hard drive platter substrate or an optical storage device substrate), a photovoltaic device substrate, a battery substrate, or the like. Embodiments including a FOUP are described for clarity, however, the method is general and may be applicable to other articles that may be conveyed and transferred from one location to another.

In step 610, the article is transported using the conveyance section. The conveyance section comprises a first transport belt and a second transport belt, the first and second transport belts separated by a distance configured for placement of the article therebetween. The first and second transport belts may be horizontal belts or vertical belts, or slanted between horizontal and vertical. The first and second transport belts may be configured using support wheels or guides to define a straight or curvilinear conveyance path for the article. One or more articles may be transported by the conveyance section at a given time.

In step 620, the article is optionally lifted above the first and second transport belts such that the article no longer contacts the first and second transport belts. The article is lifted to a height necessary to provide clearance for the article to be rotated without being obstructed by or contacting the first transport belt, second transport belt, or other structures associated with the conveyance section.

In step 630, the article is optionally rotated such that the article may pass downward between the first and second transport belts. The article may be wider in an axis perpendicular to the first and second transport belts than an axis parallel to the first and second transport belts while the article is being conveyed by the first and second transport belts. By rotating the article by approximately 90 degrees, the article may be able to pass downward between the first and second transport belts.

In step 640, the article is lowered by passing the article downward between the first transport belt and the second transport belt to an intermediate location. The article may be lowered while the first and second transport belts remain in motion. The first and second transport belts may convey other articles above the lowered article after the lowered article is below the first and second transport belts. The first and second transport belts may be tilted or moved laterally away from one another to provide more clearance between the first and second transport belts to allow the article to pass downward between the first and second transport belts.

In step 650, the article is translated beneath the conveyance section from the intermediate location to a destination location, such as a machine load port. The article may be moved laterally while the article is moved vertically, or in a step wise fashion in which the article is moved vertically while held at one horizontal position, then moved laterally while held at one vertical position, etc. The article may be rotated by various amounts, such as 90 degrees, 180 degrees, and 270 degrees, before, during, or after being translated to the destination location. The article may be supported from above, for example by a gripper, while being translated to the destination location.

Several embodiments are specifically illustrated and/or described herein. However, it will be appreciated that modifications and variations are covered by the above teachings and within the scope of the appended claims without departing from the spirit and intended scope thereof. For example, while the transportation of FOUPs in semiconductor manufacturing have been used herein as an illustrative example, systems and methods of the invention may be configured for transporting alternative materials, such as for example, substrates for the manufacture of liquid crystal, organic light emitting diode or other types of display devices, a memory substrate (such as a hard drive platter substrate or an optical storage device substrate), a photovoltaic device substrate, a battery substrate, or the like. Further, the vertical rollers and vertical belts discussed herein need not be perfectly vertical. The spacing of vertical rollers as illustrated herein is for illustrative purposes only. In various embodiments, vertical rollers may be disposed in a wide variety of spacings, from closely packed to widely dispersed including a single roller or rollers located only at each end of a belt. In various embodiments, horizontal rollers may be disposed in place of vertical rollers, and horizontal belts may be disposed in place of vertical belts.

Various disclosed elements such as transfer devices and conveyance sections may be disposed in conjunction with, coupled with, and/or integrated with various other disclosed elements so as to configure a system comprising multiple disclosed elements to transport an article from one location to another location. Disclosed elements may also be disposed in conjunction with, coupled with, and/or integrated with other elements known in the art. For example, a lift may be integrated with a turntable. As another example, a disclosed conveyance section or transfer system may be integrated with a prior art overhead hoist transport (OHT) system, roller conveyor, or other automated material handling system (AMHS). Support elements such as transition wheels and air bearings may be disposed in any appropriate location throughout a conveyance section or transfer system as appropriate to support and/or guide articles being conveyed through the conveyance section or transfer system. Attributes disclosed with respect to one disclosed element, such as a conveyance section or a transport belt, may be applicable to another disclosed element, such as a gripper or a lift.

In further embodiments of the lift 210, the lift 210 may be additionally configured to purge the interior of the FOUP 170. This would allow the FOUP 170 to be purged with a gas such as clean dry air, or nitrogen, while the FOUP 170 is engaged with the lift 210. The lift 210 may be configured with a purge port to purge the FOUP 170 while the lift 210 moves the FOUP 170 or while the lift 210 positions the FOUP 170 at a designated purge location (not shown). The designated purge location may additionally be used for temporary storage of the FOUP 170 or metrology. To accomplish the purge, the lift 210 may include one or more needle valves that are positioned to interface with the FOUP 170 via corresponding valves. For example, two such needle valves may be used to inject the gas and two may be used to allow the FOUP 170 to vent.

Each of the various belts discussed herein may be replaced by two or more belts. Likewise, each of the various belts discussed herein may be replaced by a combination of belt(s) and guide wheel(s), the guide wheels configured to support a FOUP directly without use of a belt between the guide wheel and the FOUP. In various embodiments, any one or more of the belts discussed herein are each supported by more than two guide wheels. In various embodiments, connective elements such as cables, belts, bands, chains, wire, and the like may be substituted for one another and associated support, guidance, and driving elements may be modified as appropriate to achieve the intended function using the substitute element. A single pulley may be replaced by a pulley assembly comprising more than one pulley and/or other guiding elements.

The embodiments discussed herein are illustrative of the present invention. As these embodiments of the present invention are described with reference to illustrations, various modifications or adaptations of the methods and or specific structures described may become apparent to those skilled in the art. All such modifications, adaptations, or variations that rely upon the teachings of the present invention, and through which these teachings have advanced the art, are considered to be within the spirit and scope of the present invention. Hence, these descriptions and drawings should not be considered in a limiting sense, as it is understood that the present invention is in no way limited to only the embodiments illustrated.

What is claimed is:

1. A system comprising:
a conveyance section comprising a first transport belt and a second transport belt disposed on either side of a conveyance path, the conveyance section configured to convey an article along the conveyance path, the first transport belt and the second transport belt configured to be separated by a distance suitable for placement of the article between the first transport belt and the second transport belt;
a lift configured to lower the article along a vertical axis between the first transport belt and the second transport belt; and
a hoist including
a carriage having a gripper configured to engage the article,
a connective element attached to the carriage, and
a motor external to the carriage and configured to move the carriage laterally by translating the connective element.

2. The system of claim 1, wherein the hoist and the conveyance section are integrated.

3. The system of claim 1, wherein the article comprises a FOUP.

4. The system of claim 3, wherein the lift includes a kinematic interface configured to engage with the FOUP.

5. The system of claim 3, wherein the gripper is configured to couple with a kinematic top handle disposed on the FOUP.

6. The system of claim 1, wherein the hoist and the lift are configured to be vertically aligned in a vertical plane with the conveyance section.

7. The system of claim 1, wherein the conveyance section is configured to be vertically aligned in a vertical plane with an equipment load port.

8. A method of moving an article from a conveyance section to a location, the method comprising:
transporting the article using a first transport belt and a second transport belt of the conveyance section;
lowering the article by passing the article downward between the first transport belt and the second transport belt; and
translating the article beneath the conveyance section to the location while supporting the article from above.

9. The method of claim 8, wherein lowering the article includes lifting the article from the conveyance section such that the article no longer touches the transport belts and rotating the article such that the article may pass downward between the first transport belt and the second transport belt.

10. The method of claim 8, wherein translating the article beneath the conveyance section to the location includes moving the article in a vertical direction and a horizontal direction.

11. The method of claim 8, wherein the first transport belt and the second transport belt are in motion while the article is passed therebetween.

12. The method of claim 8, wherein the article comprises a FOUP and the location comprises an equipment load port.

13. A system for transporting an article, the system comprising:
a support structure;
a carriage disposed below the support structure and configured to move laterally while being supported by the support structure;
a first connective element coupled with the carriage and approximately horizontally oriented;
a first motor coupled with the first connective element, the first motor configured to laterally translate the carriage using the first connective element; and
a gripper suspended beneath the carriage, the gripper configured to engage the article and support the article from above.

14. The system of claim 13, wherein the article comprises a FOUP.

15. The system of claim 13, wherein the first motor is disposed external to the carriage.

16. The system of claim 13, wherein the carriage includes a lift mechanism having an approximately vertically oriented connective element, the gripper is suspended below the carriage using the vertically oriented connective element, and the lift mechanism is configured to lift the gripper using the vertically oriented connective element.

17. The system of claim 16, further including
a second connective element coupled with the lift mechanism; and
a second motor coupled with the second connective element, the second motor configured translate the second connective element to cause the lift mechanism to raise or lower the gripper.

18. The system of claim 17, further including a clutch disposed between the lift mechanism and the second motor.

19. The system of claim 17, wherein the second motor is disposed external to the carriage.

20. The system of claim 17, further including a brake coupled with the lift mechanism.

21. A system for moving an article, the system comprising:
a carriage configured to move the article; and
an electrically conductive connective element coupled with the carriage, the connective element configured to laterally translate the carriage and electrically couple the carriage with an electrical source.

22. The system of claim 21, further comprising a gripper suspended below the carriage, the gripper configured to engage a FOUP.

23. The system of claim 21, further comprising a slip ring configured to electrically couple the electrically conductive connective element with the electrical source.

24. The system of claim 21, wherein the electrical source comprises an electrical power source, and the electrically conductive connective element is configured to provide electrical power to the carriage.

25. The system of claim 24, wherein the carriage comprises a first electronic data transceiver, the first electronic data transceiver configured to communicate with a second electronic data transceiver disposed external to the carriage via wireless data communications.

26. The system of claim 21, wherein the electrical source comprises a first electronic data transceiver, the carriage comprises a second electronic data transceiver, and the electrically conductive connective element is configured to communicatively couple the first and second electronic data transceivers to convey an electronic communication therebetween.

27. The system of claim 21 wherein the electrically conductive connective element comprises
a first electrically conductive segment having a first end coupled with the carriage and a second end coupled with an insulator, the first electrically conductive segment further electrically coupled with a positive power source terminal, and
a second electrically conductive segment having a first end coupled with the carriage and a second end coupled with the insulator, the second electrically conductive segment further electrically coupled with a negative power source terminal.
